(19) United States
(12) Patent Application Publication
(10) Pub. No.: US 2025/0233048 A1
(43) Pub. Date: Jul. 17, 2025

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Juno Kim, Suwon-si (KR); Minwoo Rhee, Suwon-si (KR); Sujie Kang, Suwon-si (KR); Jungshin Lee, Suwon-si (KR); Kyeongbin Lim, Suwon-si (KR)

(21) Appl. No.: 18/941,723

(22) Filed: Nov. 8, 2024

(30) Foreign Application Priority Data
Jan. 16, 2024 (KR) 10-2024-0006508

(51) Int. Cl. H01L 23/427; H01L 25/18; H10B 80/00

(52) U.S. Cl. CPC H01L 23/427; H01L 25/18; H01L 2225/06517; H01L 2225/06541; H01L 2225/06589; H10B 80/00

(57) ABSTRACT

A semiconductor package includes a mounting substrate, a semiconductor device mounted on the mounting substrate, and a first heat dissipation member disposed on the semiconductor device. The first heat dissipation member includes a first heat dissipation substrate directly bonded to an upper surface of the semiconductor device, a first micro channel extending within the first heat dissipation substrate, and a first working fluid movably accommodated in the first micro channel and including liquid slugs and gaseous plugs that are alternately disposed along an extending direction of the first micro channel.

### CROSS-REFERENCE TO RELATED APPLICATION(S)

This application claims priority to Korean Patent Application No. 10-2024-0006508, filed in the Korean Intellectual Property Office (KIPO) on Jan. 16, 2024, which is incorporated by reference herein in its entirety.

### BACKGROUND

In semiconductor packages, such as high bandwidth memory (HBM) devices or 3D IC packages, heat generated from semiconductor devices bonded to each other may not be dispersed efficiently and hot spots may occur within the semiconductor device. In order to reduce a thermal resistance of the semiconductor package, a heat dissipation member may be attached to a top of the semiconductor device to improve heat diffusion. However, since the existing heat dissipation member is attached using a thermal interface material (TIM), the thermal conductivity of the thermal interface material layer may be very low, which increases the contact resistance between the heat dissipation member and the semiconductor device.

### SUMMARY

In general, in some aspects, the present disclosure is directed toward an electronic device having a heat dissipation structure that has improved heat dissipation performance and is able to reduce overall height.

According to some implementations, the present disclosure is directed to a semiconductor package that includes a mounting substrate, a semiconductor device mounted on the mounting substrate, and a first heat dissipation member disposed on the semiconductor device. The first heat dissipation member includes a first heat dissipation substrate directly bonded to an upper surface of the semiconductor device, a first micro channel extending within the first heat dissipation substrate, and a first working fluid movably accommodated in the first micro channel and including liquid slugs and gaseous plugs that are alternately disposed along an extending direction of the first micro channel.

According to some implementations, the present disclosure is directed to a semiconductor package that includes a mounting substrate, a first semiconductor device and a second semiconductor device mounted on the mounting substrate and spaced apart from each other, and a first heat dissipation member disposed on the first semiconductor device and the second semiconductor device. The first heat dissipation member includes a first heat dissipation substrate directly bonded to an upper surface of the first semiconductor device, a first micro channel extending within the first heat dissipation substrate, and a first working fluid movably accommodated in the first micro channel and including liquid slugs and gaseous plugs that are alternately disposed along an extending direction of the first micro channel.

According to some implementations, the present disclosure is directed to a semiconductor package that includes a mounting substrate, a semiconductor device mounted on the mounting substrate, a first heat dissipation member spaced apart from the semiconductor device on the mounting substrate, and a second heat dissipation member disposed on the semiconductor device and the first heat dissipation member. The second heat dissipation member is directly bonded to the semiconductor device and the first heat dissipation member, respectively. The second heat dissipation member includes a second heat dissipation substrate directly bonded to an upper surface of the semiconductor device, and a second pulsating heat pipe extending within the second heat dissipation substrate.

According to some implementations, the present disclosure is directed to a semiconductor package that includes a mounting substrate, a semiconductor device mounted on the mounting substrate, and a first heat dissipation member on the semiconductor device and thermally connected to the semiconductor device. The first heat dissipation member may include a first heat dissipation substrate directly bonded to an upper surface of the semiconductor device, a first micro channel extending within the first heat dissipation substrate, and a first working fluid movably accommodated within the first micro channel and including liquid slugs and gaseous plugs that are alternately disposed along an extending direction of the first micro channel.

According to some implementations, since the first heat dissipation substrate is directly bonded to the semiconductor device without using a thermal interface material layer, voids at the interface may be eliminated and contact resistance at the interface may be reduced. Further, since the first heat dissipation substrate has a coefficient of thermal expansion similar to that of the semiconductor device, internal stress due to changes in the environment between the bonded semiconductor device and the first heat dissipation substrate may be prevented from occurring, to thereby improve the thermo-mechanical reliability of the semiconductor device.

### BRIEF DESCRIPTION OF THE DRAWINGS

Example implementations will be more clearly understood from the following detailed description, taken in conjunction with the accompanying drawings.

FIG. 1 is a cross-sectional view illustrating an example of a semiconductor package according to some implementations.

FIG. 2 is an enlarged cross-sectional view illustrating an example of a portion ‘A’ in FIG. 1 according to some implementations.

FIG. 3 is a plan view illustrating an example of a heat dissipation member in FIG. 1 according to some implementations.

FIG. 4 is an enlarged cross-sectional view illustrating an example of a portion ‘C’ in FIG. 3 according to some implementations.

FIGS. 5 to 12 are views illustrating an example of a method of manufacturing a semiconductor package according to some implementations.

FIG. 13 is a cross-sectional view illustrating an example of a semiconductor package according to some implementations.

FIGS. 14 to 19 are views illustrating an example of a method of manufacturing a semiconductor package according to some implementations.

FIG. 20 is a plan view illustrating an example of a heat dissipation member bonded to a semiconductor device according to some implementations.

### DETAILED DESCRIPTION

Hereinafter, example implementations will be explained in detail with reference to the accompanying drawings.

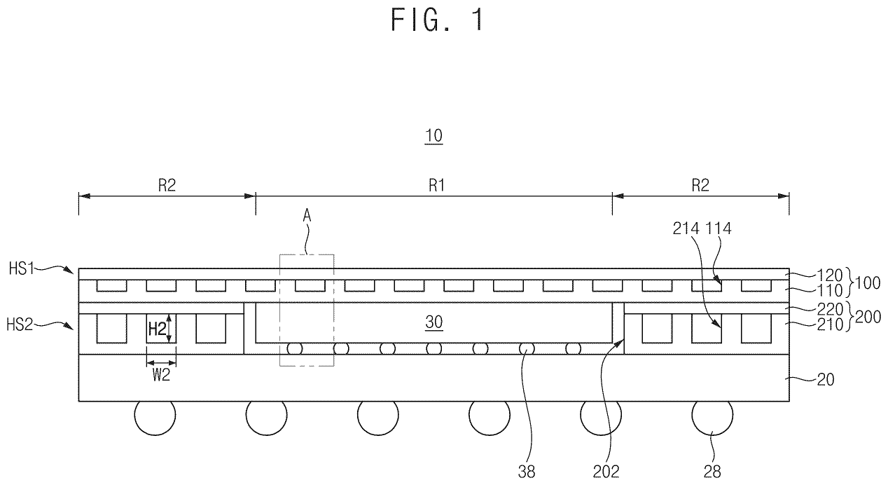

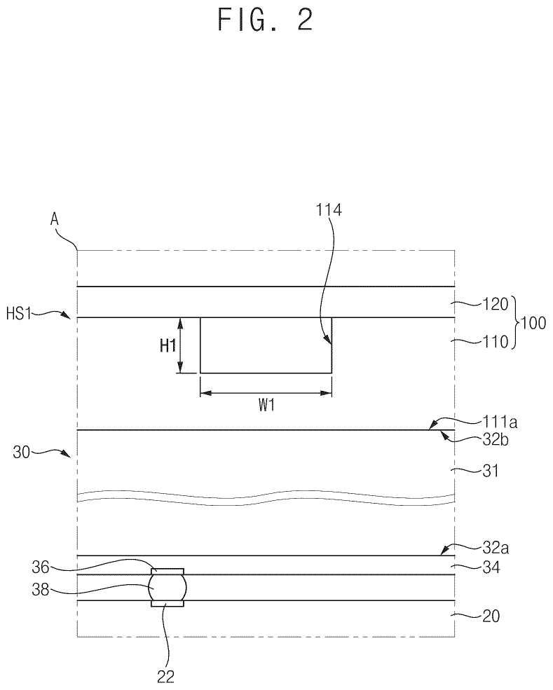

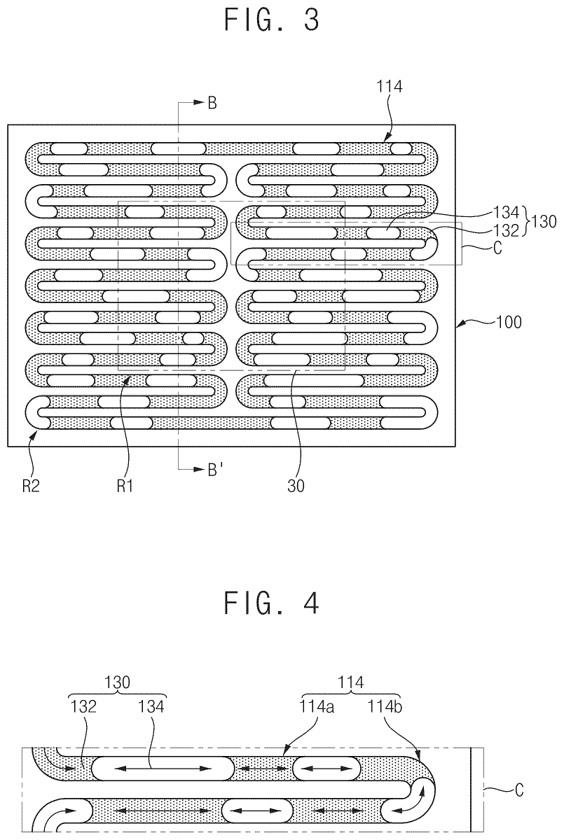

FIG. 1 is a cross-sectional view illustrating an example of a semiconductor package according to some implementations. FIG. 2 is an enlarged cross-sectional view illustrating an example of a portion ‘A’ in FIG. 1 according to some implementations. FIG. 3 is a plan view illustrating an example of a heat dissipation member in FIG. 1 according to some implementations. FIG. 4 is an enlarged cross-sectional view illustrating an example of a portion ‘C’ in FIG. 3 according to some implementations. FIG. 1 is a cross-sectional view taken along the line B-B′ in FIG. 2.

In FIGS. 1 to 4, a semiconductor package 10 may include a mounting substrate 20 as a package substrate, a semiconductor device 30 mounted on the mounting substrate 20, and a first heat dissipation member HS1 on the semiconductor device 30 and thermally connected to the semiconductor device 30. Additionally, the semiconductor package 10 may further include a second heat dissipation member HS2. The semiconductor package 10 may further include external connection members 28 provided on a lower surface of the mounting substrate 20.

In some implementations, the semiconductor package 10 may be a multi-chip package (MCP) including different types of semiconductor chips. The semiconductor package 10 may be a system in package (SIP) including a plurality of semiconductor chips that perform multiple functions in one package. The semiconductor device 30 may include a logic semiconductor chip. The logic semiconductor chip may be an ASIC as a host such as CPU, GPU, or SoC.

In FIGS. 1 and 2, the mounting substrate 20 may be provided as a substrate such as a printed circuit board. The mounting substrate 20 may be a substrate having an upper surface and a lower surface opposite to the upper surface. The mounting substrate 20 may include a coreless substrate, a core multilayer substrate, or an interposer substrate.

In some implementations, the semiconductor device 30 may be mounted on the mounting substrate 20 by a flip chip bonding process. The semiconductor device 30 may be arranged such that a first surface (active surface) 32a on which chip pads 36 are formed faces the mounting substrate 20. The chip pads 36 of the semiconductor device 30 may be electrically connected to substrate pad 22 of the mounting substrate 20 through conductive bumps 38. For example, the conductive bumps include a conductive material, such as copper (Cu), nickel (Ni), tin (Sn), tin/silver (Sn/Ag), tin/copper (Sn/Cu), tin/indium (Sn/In), etc.

The semiconductor device 30 may include a substrate 31 and a wiring layer 34. The substrate 31 may have a first surface 32a and a second surface 32b opposite to the first surface 32a. The first surface may be the active surface, and the second surface may be an inactive surface. Circuit patterns and cells may be formed in the first surface 32a of the substrate 31. For example, the substrate 31 may be a single crystal silicon substrate. The circuit patterns may include transistors, capacitors, diodes, etc. The circuit patterns may constitute circuit elements.

The wiring layer 34 may be provided on the first surface 32a of the substrate 31, that is, the active surface. The wiring layer 34 may include a plurality of insulating layers and wirings in the insulating layers. Additionally, redistribution pads may be provided in an outermost insulating layer of the wiring layer 34, and the chip pads 36 may be provided on the redistribution pads. Accordingly, the chip pads 36 may be provided in an outer surface of the wiring layer 34.

In some implementations, the first heat dissipation member HS1 as a first heat spreader may cover the semiconductor device 30 and may be thermally connected to the semiconductor device 30 to dissipate heat from the semiconductor device 30 to the outside. The first heat dissipation member HS1 may include a first heat dissipation substrate 100 directly bonded to the upper surface 32b of the semiconductor device 30 and a first pulsating heat pipe extending horizontally in the first heat dissipation substrate 100. The first pulsating heat pipe may include a first micro channel 114 that extends horizontally in the first heat dissipation substrate 100, and a first working fluid 130 that is movably accommodated within the first micro channel 114. The horizontal direction may be perpendicular to a thickness direction of the first heat dissipation substrate 100.

The first heat dissipation substrate 100 may include a first lower substrate 110 and a first upper substrate 120. A lower surface 111a of the first lower substrate 110 may be directly bonded to the upper surface 32b of the semiconductor device 30. A first recess may be formed in an upper surface of the first lower substrate 110. The first upper substrate 120 may be directly bonded to the first lower substrate 110. The first upper substrate 120 may cover the first recess of the first lower substrate 110 to define the first micro channel 114.

The first heat dissipation substrate 100 may include a material that can be directly bonded to the semiconductor device 30 without using a thermal interface material (TIM). For example, the first heat dissipation substrate 100 may be bonded to the backside surface 32b of the semiconductor device 30 by fusion bonding, anodic bonding, diffusion bonding, eutectic bonding, thermal compression bonding, etc. The bonding method of the first heat dissipation substrate 100 may be determined depending on a material of the interface to be bonded.

Additionally, the first heat dissipation substrate 100 may include a material having a coefficient of thermal expansion (CTE) similar to that of the semiconductor device 30. For thermo-mechanical reliability of the semiconductor device 30, internal stress due to changes in the environment (temperature, humidity) should not be generated between the bonded semiconductor device 30 and the first heat dissipation substrate 100. If the internal stress occurs, cracks may occur at the joint, leading to delamination. In order to prevent such internal stress from occurring, the semiconductor device 30 and the first heat dissipation substrate 100 to be joined may be selected to include materials having similar coefficients of thermal expansion (CTE).

For example, the first heat dissipation substrate 100 may include a semiconductor material, a polymer material, such as plastic, ceramic, etc. with a coefficient of thermal expansion (CTE) similar to that of silicon. The first heat dissipation substrate 100 may include silicon (Si), silicon carbide (SiC), aluminum nitride (AlN), etc. The thermal conductivity of silicon may be 150 W/mK and the coefficient of thermal expansion of silicon may be 3 ppm/° C. to 5 ppm/° C. The thermal conductivity of silicon carbide may be 300 W/mK to 500 W/mK and the coefficient of thermal expansion of silicon carbide may be 2.7 ppm/° C. The thermal conductivity of aluminum nitride may be 300 W/mK to 400 W/mK and the coefficient of thermal expansion of aluminum nitride may be 5.3 ppm/° C.

In FIGS. 3 and 4, the first heat dissipation member HS1 may include a first heat dissipation portion R1 overlapping the semiconductor device 30 and a second heat dissipation portion R2 surrounding the first heat dissipation portion R1. The first micro channel 114 may extend within the first heat dissipation substrate 100 and may have a sealed heat pipe structure. The first micro channel 114 may have a structure in which one long capillary tube extends tortuously. The first micro channel 114 may have straight extension portion portions 114a extending in a straight line and curved extension portions 114b connecting the straight extension portions 114a. The curved extension portion 114b may be U-shaped.

The first working fluid 130 may fill a portion of a sealed internal space of the first micro channel 114. The first working fluid 130 may fill 10% to 90% of the sealed internal space. The first working fluid 130 may be in a two-phase state, that is, the first working fluid 130 may include a liquid slug 132 and a gaseous plug 134. The liquid slug 132 and the gaseous plug 134 may be alternately arranged along an extending direction of the first micro channel 114.

The first working fluid 130 may include an insulation (dielectric) solution (dielectric fluid). For example, the first working fluid may include mineral oil, hexane, heptane, castor oil, natural ester oil, synthetic esters, silicon oil, fluorine inert liquid, polychlorinated biphenyl, purified water, benzene, liquid oxygen, liquid nitrogen, liquid hydrogen, liquid helium, liquid argon, etc.

The curved extension portions 114b may be disposed in the first heat dissipation portion R1, and the straight extension portions 114a may extend from the first heat dissipation portion R1 to the second heat dissipation portion R2. The first heat dissipating portion R1 may serve as an evaporator that absorbs heat generated from the semiconductor device 30, which is a heating element, and the second heat dissipating portion R2 may serve as a condenser that transfers and emits the heat absorbed from the evaporator R1 to the outside. The working fluid 130 in the evaporator may receive heat from the heating element to be vaporized, and then, may move to the condenser. The working fluid 130 in the condensation unit may be condensed by an external cooling source. The heat of the heating element may be continuously transferred to the condenser by this thermally driven self-pulsating flow.

A phase change (between gas phase and liquid phase) of the working fluid 130 inside the first heat dissipation member HS1 may occur, thereby providing high heat transfer capacity. The first heat dissipation member HS1 may have a very high heat transfer coefficient due to heat transfer by phase change. An effective thermal conductivity of the first heat dissipation member HS1 of the 1 mm level silicon substrate may be within a range of 4,000 W/mK to 6,000 W/mK.

In the first heat dissipation member HS1, the first working fluid 130, in which the liquid slug 132 and the gaseous plug 134 are alternately disposed within the first micro channel 114, may be oscillated in the form of a vibration due to a change in the pressure of the gaseous plug 134 due to thermal energy to exhibit a pulsating motion and may transfer the heat from the heating element to a cooling portion. Because the movement of the gas phase and the liquid phase are on the same plane, the first heat dissipation substrate 100 may be made thinner. For example, a thickness of the first heat dissipation member HS1 may be within the range of 100 um to 800 um. A width W1 of the first micro channel 114 may be in a range of 100 μm to 1,000 μm, and a height H1 of the first micro channel 114 may be within the range of 50 μm to 500 μm.

In some implementations, the second heat dissipation member HS2 as a second heat spreader may be spaced apart from the semiconductor device 30 on the mounting substrate 20. The second heat dissipation member HS2 may have a cavity 202 for accommodating the semiconductor device 30 in a middle region thereof. The semiconductor device 30 may be disposed within the cavity 202 of the second heat dissipation member HS2. In some implementations, a plurality of the second heat dissipation members HS2 may be arranged to surround the semiconductor device 30. In this case, four second heat dissipation members HS2 may be disposed adjacent to four side surfaces of the square-shaped semiconductor device 30 respectively.

The second heat dissipation member HS2 may include a second heat dissipation substrate 200 directly bonded to an upper surface of the mounting substrate 20 and a second pulsating heat pipe extending horizontally in the second heat dissipation substrate 200. The second pulsating heat pipe may include a second micro channel 214 that extends horizontally within the second heat dissipation substrate 200, and a second working fluid that is movably accommodated within the second micro channel 214.

The second heat dissipation substrate 200 may include a second lower substrate 210 and a second upper substrate 220. A lower surface of the second lower substrate 210 may be directly bonded to the upper surface of the mounting substrate 20. A recess may be formed in an upper surface of the second lower substrate 210. The second upper substrate 220 may be directly bonded to the second lower substrate 210. The second upper substrate 220 may cover the recess of the second lower substrate 210 to define the second micro channel 214.

The semiconductor device 30 may have a first height from the upper surface of the mounting substrate 20, and the second heat dissipation member HS2 may have a second height from the upper surface of the mounting substrate 20. For example, the first height may be substantially the same as the second height. The first heat dissipation member HS1 may be disposed on the semiconductor device 30 and the second heat dissipation member HS2.

The first heat dissipation member HS1 may be thermally connected to the second heat dissipation member HS2 and may dissipate heat from the semiconductor device 30 to the outside. Heat from the semiconductor device 30 may be transferred to the second heat dissipation member HS2 through the first heat dissipation member HS1 and then discharged to the outside. Additionally, heat from the semiconductor device 30 may be directly transferred to the second heat dissipation member HS2 and then dissipated to the outside. The first heat dissipation member HS1 may be directly bonded to the second heat dissipation member HS2. The lower surface 111a of the first lower substrate 110 may be directly bonded to the upper surface of the second upper substrate 220.

The second heat dissipation substrate 200 may be substantially the same as or similar to the first heat dissipation substrate 100. Accordingly, the same or similar reference numerals may be used to refer to the same or like elements and any further repetitive explanation concerning the above elements will be omitted.

In the drawings, a single semiconductor device is illustrated, but in some implementations, the semiconductor package as a multi-chip package may include a plurality of semiconductor chips on which the semiconductor device is stacked or may include a plurality of semiconductor devices spaced apart from each other on the mounting substrate.

Additionally, the semiconductor package 10 may further include a heat sink that is thermally connected to the first heat dissipation member HS1 to cover at least a portion of an upper surface of the first heat dissipation member HS1. The heat sink may be detachably mounted on the upper surface of the first heat dissipation member HS1. For example, the heat sink may include a thermally conductive base plate covering the upper surface of the first heat dissipation member HS1 and a plurality of heat dissipation fins protruding upward from the base plate.

In some implementations, external connection pads may be provided in the lower surface of the mounting substrate 20, and the external connection members 28 may be disposed on the external connection pads, respectively. For example, the external connection member 28 may include a solder ball. The semiconductor package 10 may be mounted on a module substrate using the solder balls to form a memory module.

As described above, the semiconductor package 10 may include the mounting substrate 20, the semiconductor device 30 mounted on the mounting substrate 20, and the first heat dissipation member HS1 thermally connected to the semiconductor device 30 on the semiconductor device 30. The first heat dissipation member HS1 may include the first heat dissipation substrate 100 directly bonded to the upper surface of the semiconductor device 30, the first micro channel 114 extending within the first heat dissipation substrate 100, and the first working fluid 130 movably accommodated within the first micro channel 114 and including the liquid slugs 132 and the gaseous plugs 134 that are alternately disposed along the extending direction of the first micro channel 114.

Since the first heat dissipation substrate 100 is directly bonded to the semiconductor device 30 without using a thermal interface material layer, voids at the interface may be eliminated and contact resistance at the interface may be reduced. Further, since the first heat dissipation substrate 100 has the coefficient of thermal expansion similar to that of the semiconductor device 30, internal stress due to changes in the environment (temperature, humidity) between the bonded semiconductor device 30 and the first heat dissipation substrate 100 may be prevented from occurring, to thereby improve the thermo-mechanical reliability of the semiconductor device 30.

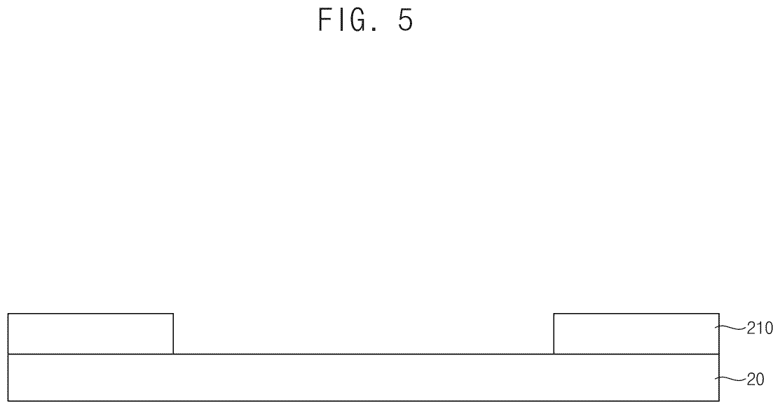

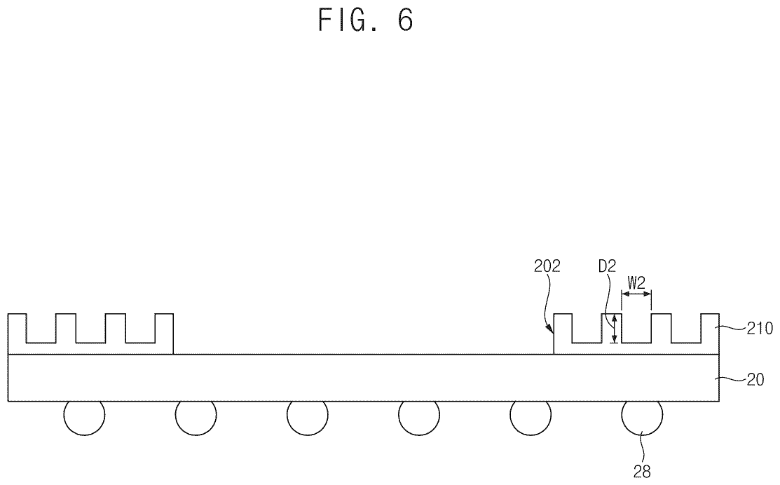

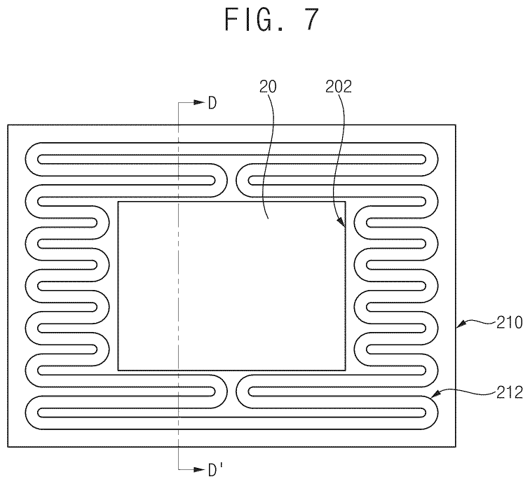

FIGS. 5 to 12 are views illustrating an example of a method of manufacturing a semiconductor package according to some implementations. FIG. 7 is a plan view of FIG. 6 according to some implementations, and FIG. 6 is a cross-sectional view taken along the line D-D′ in FIG. 7 according to some implementations.

In FIGS. 5 to 8, a second heat dissipation member HS2 as a second heat spreader may be disposed on a mounting substrate 20, and a second lower substrate 210 may be bonded to the mounting substrate 20. The second lower substrate 210 may include a material that can be directly bonded to the mounting substrate 20 without using an adhesive film. For example, the second lower substrate 210 may be bonded to an upper surface of the mounting substrate 20 by fusion bonding, anodic bonding, diffusion bonding, eutectic bonding, thermal compression bonding, etc. The method of bonding the second lower substrate 210 may be determined depending on a material of the upper surface of the mounting substrate 20.

For example, the second lower substrate 210 may include a semiconductor material, a polymer material, such as plastic, ceramic, etc., with a coefficient of thermal expansion (CTE) similar to that of silicon. The second lower substrate 210 may include silicon (Si), silicon carbide (SiC), aluminum nitride (AlN), etc.

The second lower substrate 210 may have a cavity 202 in its middle region. As described below, a semiconductor device may be disposed within the cavity 202 of the second lower substrate 210.

In FIGS. 6 and 7, a second recess 212 for forming a second micro channel may be formed in an upper surface of the second lower substrate 210. The second recess 212 may be formed by an etching process. The etching process may be an isotropic dry etching process. The etching process may include a plasma etching process, etc. The plasma etching process may be performed using inductively coupled plasma, capacitively coupled plasma, microwave plasma, etc.

The second recess may have straight extension portions extending in a straight line and curved extension portions connecting the straight extension portions. The curved extension portion may be U-shaped. For example, a width W2 of the second recess 212 may be within a range of 100 μm to 1,000 μm, and a depth D2 of the second recess 212 may be within a range of 50 μm to 500 μm.

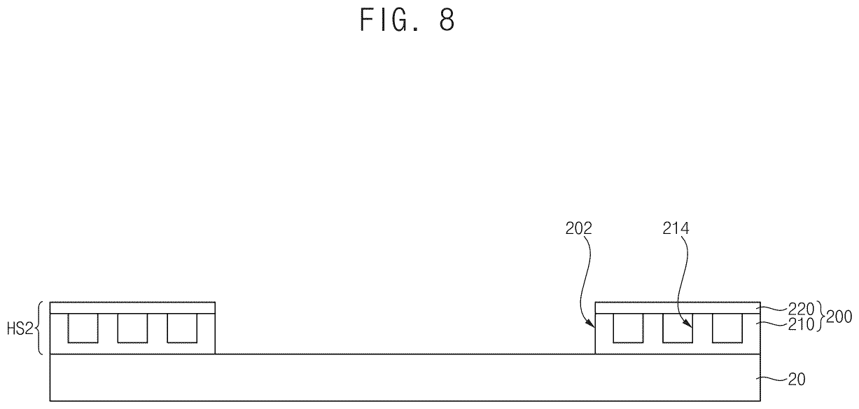

In FIG. 8, a second upper substrate 220 may be bonded to the second lower substrate 210 to form a second micro channel 214, and a second working fluid may be injected into the second micro channel 214 to form the second heat dissipation member HS2. The second upper substrate 220 may be directly bonded to the first upper substrate 210 to form the second heat dissipation substrate 200. For example, the second upper substrate 220 may be bonded to the upper surface of the second lower substrate 210 by fusion bonding, anodic bonding, diffusion bonding, eutectic bonding, thermal compression bonding, etc. As the second upper substrate 220 is bonded to the first upper substrate 210, the second upper substrate 220 may cover the second recess 212 to form the second micro channel 214.

For example, the second upper substrate 220 may include a material that can be directly bonded to the second lower substrate 210. The second upper substrate 220 may include a material the same as the second lower substrate 210.

The second micro channel 214 may extend within the second heat dissipation substrate 200 and may have a sealed heat pipe structure. The second micro channel 214 may have a structure in which one long capillary tube that extends tortuously. After filling a portion of a sealed internal space of the second micro channel 214 with the second working fluid, the sealed structure may be formed to prevent the second working fluid from leaking. The second working fluid may fill 10% to 90% of the sealed internal space of the second micro channel 214.

The second working fluid may include an insulation solution (dielectric fluid). For example, the second working fluid may be mineral oil, hexane, heptane, castor oil, natural ester oil, synthetic esters, silicon oil, fluorine inert liquid, polychlorinated biphenyl, purified water, benzene, liquid oxygen, liquid nitrogen, liquid hydrogen, liquid helium, liquid argon, etc.

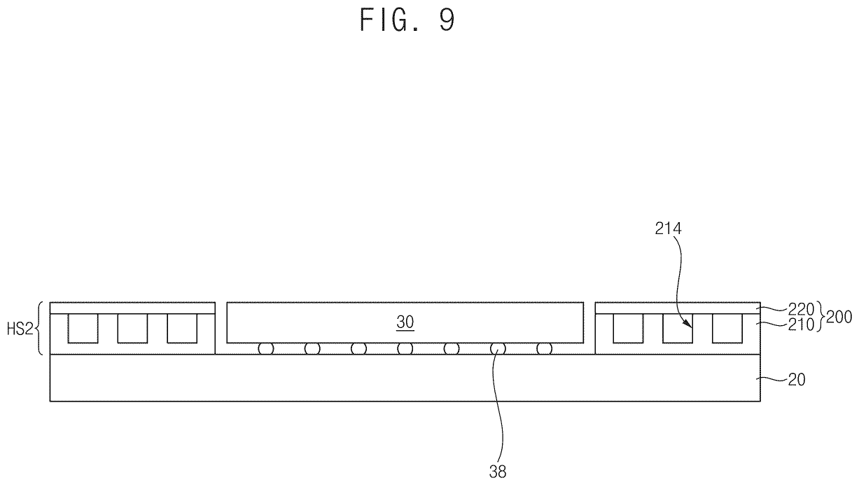

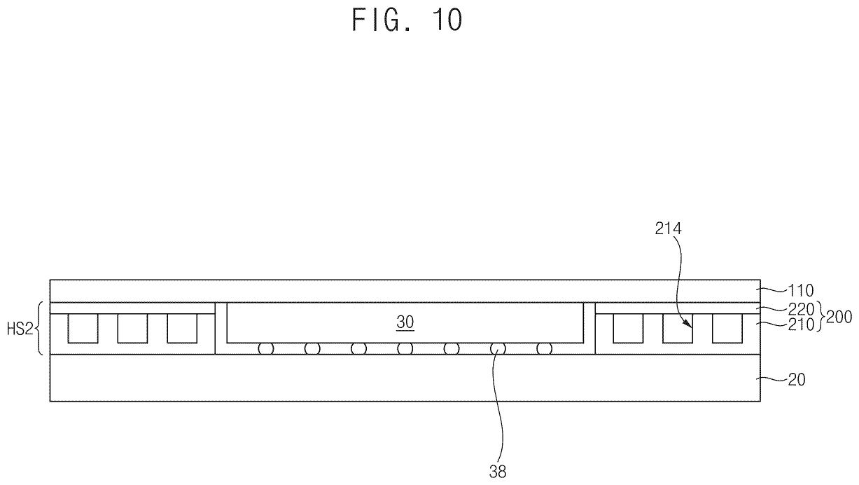

In FIG. 9, a semiconductor device 30 may be mounted on the mounting substrate 20. The semiconductor device 30 may be disposed within the cavity 202 of the second heat dissipation member HS2.

In some implementations, the semiconductor device 30 may be mounted on the mounting substrate 20 via conductive bumps 38. The semiconductor device 30 may be disposed such that a front surface on which chip pads are formed, that is, an active surface, faces the mounting substrate 20. The semiconductor device 30 may have a rectangular shape with four sides when viewed in plan view. The chip pads may be arranged in an array form over the entire front surface of the semiconductor device 30.

The semiconductor device 30 may be a logic chip including a logic circuit. The semiconductor device may be a processor chip or an application processor AP, such as an ASIC, as a host, such as CPU, GPU, or SOC,

The semiconductor device 30 may have a first height from the upper surface of the mounting substrate 20, and the second heat dissipation member HS2 may have a second height from the upper surface of the mounting substrate 20. For example, the first height may be substantially the same as the second height.

In FIGS. 10 to 12, processes the same as or similar as described with reference to FIGS. 5 to 8 may be performed to dispose a first heat dissipation member HS1 as a first heat spreader on the semiconductor device 30 and the second heat dissipation member HS2.

In FIG. 10, a first lower substrate 110 may be bonded to the semiconductor device 30. The first lower substrate 110 may be bonded to the second heat dissipation member HS2. The first lower substrate 110 may include a material that can be directly bonded to the semiconductor device 30 and the second heat dissipation member HS2 without using a contact film. For example, the first lower substrate 110 may be bonded to an upper surface of the semiconductor device 30 and an upper surface of the second heat dissipation member HS2 by fusion bonding, anodic bonding, diffusion bonding, eutectic bonding, thermal compression bonding, etc. The method of bonding the first lower substrate 110 may be determined depending on the materials of the upper surfaces of the semiconductor device 30 and the second heat dissipation member HS2. For example, the first lower substrate 110 may include a semiconductor material, a polymer material, such as plastic, ceramic, etc., with a coefficient of thermal expansion (CTE) similar to that of silicon. The first lower substrate 110 may include the same material as the second upper substrate 220.

When the first lower substrate 110 and the semiconductor device 30 include a silicon material, the first lower substrate 110 may be bonded to the semiconductor device 30 by the fusion bonding. For example, pretreatment may be performed on at least one of the surfaces of the first lower substrate 110 and the semiconductor device 30 that are bonded to each other. A plasma gas may be supplied through a shower head on the bonding surface within a chamber of a plasma processing apparatus, and plasma processing may be performed within the chamber. Then, the plasma treated bonding surface may be cleaned. DI water may be coated on the bonding surface using a spin coater. The DI water may not only clean the bonding surface, but also allow —OH groups to bond well to the bonding surface, making it easier to form a dangling bond on the bonding surface. After aligning the pretreated first lower substrate 110 and the semiconductor device 30, the first lower substrate 110 and the semiconductor device 30 may be pressed and bonded to each other.

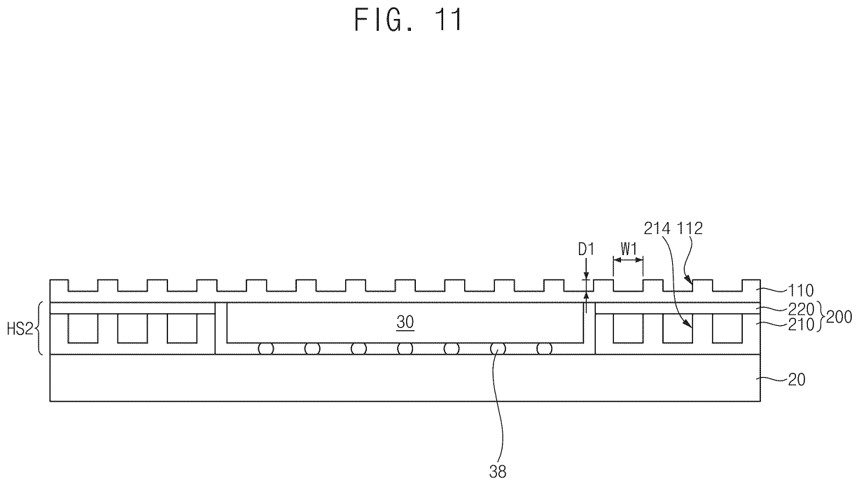

In FIG. 11, a first recess 112 for forming a first micro channel may be formed in an upper surface of the first lower substrate 110. The first recess 112 may be formed by an etching process. The first recess may have straight extension portions extending in a straight line and curved extension portions connecting the straight extension portions. The curved extension portion may be U-shaped. For example, a width W1 of the first recess 112 may be within a range of 100 μm to 1,000 μm, and a depth D1 of the first recess 112 may be within a range of 50 μm to 500 μm.

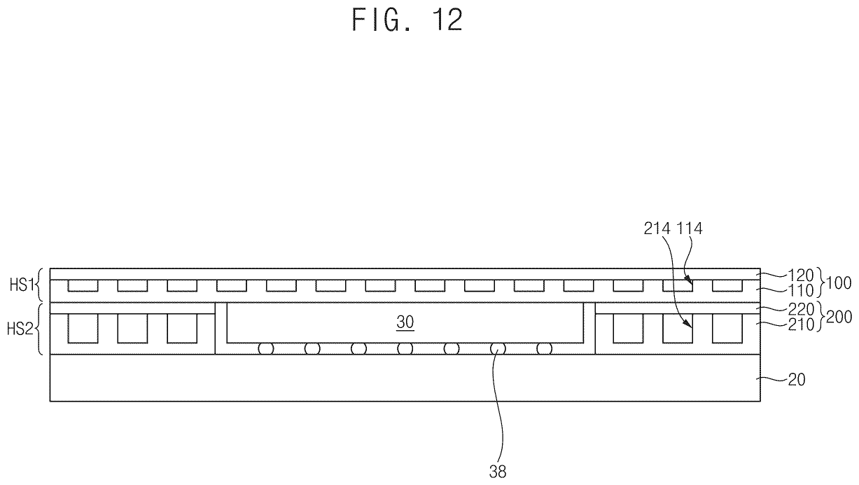

In FIG. 12, a first upper substrate 120 may be bonded to the first lower substrate 110 to form a first micro channel 114, and a first working fluid may be injected into the first micro channel 114 to form the first heat dissipation member HS1.

The first upper substrate 120 may be directly bonded to the first lower substrate 110 to form the first heat dissipation substrate 100. For example, the first upper substrate 120 may be bonded to the upper surface of the first lower substrate 110 by fusion bonding, anodic bonding, diffusion bonding, eutectic bonding, thermal compression bonding, etc. As the first upper substrate 120 is bonded to the first lower substrate 110, the first upper substrate 120 may cover the first recess 112 to form the first micro channel 214.

For example, the first upper substrate 120 may include a material that can be directly bonded to the first lower substrate 110. The first upper substrate 120 may include a material the same as the first lower substrate 110.

The first micro channel 114 may extend within the first heat dissipation substrate 100 and may have a sealed heat pipe structure. The first micro channel 114 may have a structure in which one long capillary tube extends tortuously. After filling a portion of a sealed internal space of the first micro channel 114 with the first working fluid, a sealed structure may be formed to prevent the first working fluid from leaking. The first working fluid may fill 10% to 90% of the sealed internal space of the first micro channel 114. The first working fluid may include an insulation solution (dielectric fluid).

Then, external connection members 28 (see FIG. 1) may be formed on external connection pads on a lower surface of the mounting substrate 20 to complete a semiconductor package 10 (see FIG. 1).

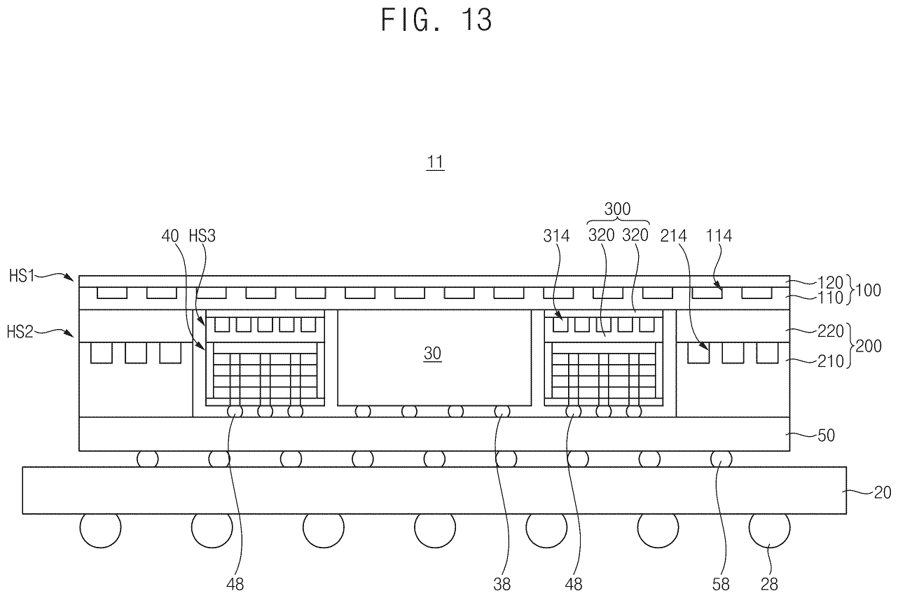

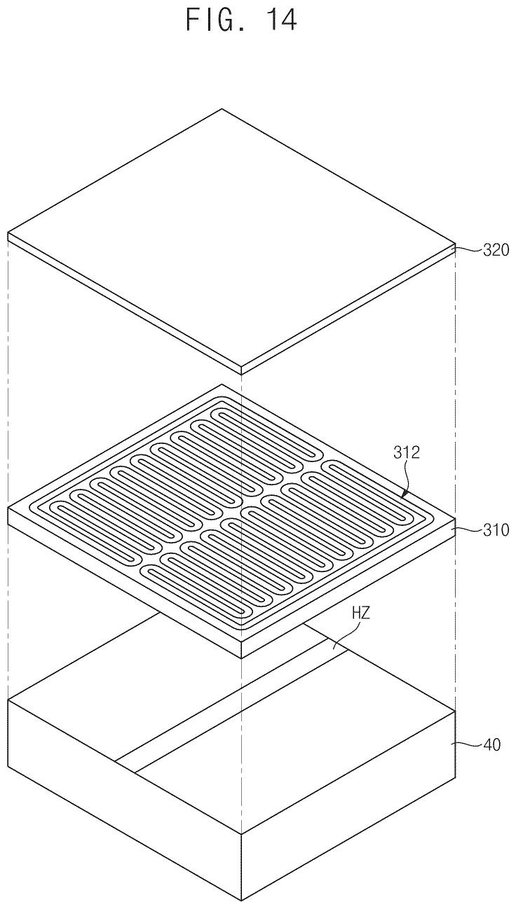

FIG. 13 is a cross-sectional view illustrating an example of a semiconductor package according to some implementations. The semiconductor package may be substantially the same as or similar to the semiconductor package described with reference to FIGS. 1 to 4, except for a first semiconductor device and a second semiconductor device mounted on an interposer. Accordingly, same reference numerals may be used to refer to the same or like elements and any further repetitive explanation concerning the above elements will be omitted.

In FIG. 13, a semiconductor package 11 may include an interposer 50, a first semiconductor device 30 and a second semiconductor device 40 respectively disposed on the interposer 50, and a first heat dissipation member HS1 thermally connected to the first semiconductor device 30 on the first semiconductor device 30. Additionally, the semiconductor package 11 may further include a second heat dissipation member HS2, a third heat dissipation member 300, and a package substrate 20. The semiconductor package 11 may further include external connection members 28 provided on a lower surface of the package substrate 20.

In some implementations, the semiconductor package 11 may be provided as a portion of a memory module with a 2.5D package structure. In this case, the first semiconductor device 30 may include a logic semiconductor device, and the second semiconductor device 40 may include a memory device. The logic semiconductor device may be an ASIC as a host, such as a CPU, GPU, or SoC. The memory device may include a high bandwidth memory (HBM) device.

The first semiconductor device 30 and the second semiconductor device 40 may be mounted on the interposer 50. The first semiconductor device 30 and the second semiconductor device 40 may be arranged on the interposer 50 to be spaced apart from each other along a first direction. Two second semiconductor devices 40 may be disposed in both sides of the first semiconductor device 30. The first semiconductor device 30 may be mounted on the interposer 50 through solder bumps 38, and the second semiconductor device 40 may be mounted on the interposer 50 through solder bumps 48.

The second semiconductor device 40 may include a buffer die that functions as circuitry and a plurality of memory dies (chips) sequentially stacked on the buffer die. The buffer die and the memory die may be electrically connected to each other through through-silicon vias. The through-silicon vias may be electrically connected to each other by solder bumps 38. The buffer die and the memory die may communicate data signals and control signals through the through-silicon vias.

The interposer 50 may be provided as a mounting substrate having connection wires therein. The interposer 50 may mount the first and second semiconductor devices 30 and 40 and electrically connect them to each other. The first and second semiconductor devices 30 and 40 may be connected to each other through the connection wires inside the interposer 50.

In some implementations, the first heat dissipation member HS1 as a first heat spreader may cover the first semiconductor device 30 and may be thermally connected to the first semiconductor device 30 to dissipate heat from the first semiconductor device 30 to the outside. The first heat dissipation member HS1 may include a first heat dissipation substrate 100 directly bonded to an upper surface of the first semiconductor device 30, a first micro channel 114 extending within the first heat dissipation substrate 100, and a first working fluid movably accommodated within the first micro channel 114.

The first heat dissipation substrate 100 may include a first lower substrate 110 and a first upper substrate 120. A lower surface of the first lower substrate 110 may be directly bonded to the upper surface of the first semiconductor device 30. A recess may be formed in an upper surface of the first lower substrate 110. The first upper substrate 120 may be directly bonded to the first lower substrate 110. The first upper substrate 120 may cover the recess of the first lower substrate 110 to define the first micro channel 114.

The first heat dissipation substrate 100 may include a material that can be directly bonded to the first semiconductor device 30 without using a thermal interface material (TIM). Additionally, the first heat dissipation substrate 100 may include a material having a coefficient of thermal expansion similar to that of the first semiconductor device 30.

The first working fluid may fill a portion of a sealed internal space of the first micro channel 114. The first working fluid may include a liquid slug and a gaseous plug. The liquid slug and the gaseous plug may be alternately arranged along an extending direction of the first micro channel 114. The first working fluid 130 may include an insulation solution (dielectric fluid).

In some implementations, the second heat dissipation member HS2 serving as a second heat spreader may be spaced apart from the second semiconductor device 40 on the interposer 50. The second heat dissipation member HS2 may have a cavity in a middle region thereof to accommodate the first semiconductor device 30 and the second semiconductor devices 40. The first and second semiconductor devices 30 and 40 may be disposed within the cavity of the second heat dissipation member HS2. Alternatively, a plurality of the second heat dissipation members HS2 may be arranged to surround the first and second semiconductor devices 30 and 40

The second heat dissipation member HS2 may include a second heat dissipation substrate 200 directly bonded to the upper surface of the interposer 50, a second micro channel 214 extending within the second heat dissipation substrate 200, and a second working fluid movably accommodated within the micro channel 214.

The second heat dissipation substrate 200 may include a second lower substrate 210 and a second upper substrate 220. A lower surface of the second lower substrate 210 may be directly bonded to the upper surface of the mounting substrate 20. A recess may be formed in an upper surface of the second lower substrate 210. The second upper substrate 220 may be directly bonded to the second lower substrate 210. The second upper substrate 220 may cover the recess of the second lower substrate 210 to define the second micro channel 214.

The first semiconductor device 30 may have a first height from the upper surface of the interposer 50, and the second heat dissipation member HS2 may have a second height from the upper surface of the interposer 50. For example, the first height may be substantially the same as the second height. The first heat dissipation member HS1 may be disposed on the first semiconductor device 30 and the second heat dissipation member HS2.

The first heat dissipation member HS1 may be thermally connected to the second heat dissipation member HS2 and may dissipate heat from the first semiconductor device 30 to the outside. The first heat dissipation member HS1 may be directly bonded to the second heat dissipation member HS2. The lower surface of the first lower substrate 110 may be directly bonded to an upper surface of the second upper substrate 220.

The second heat dissipation substrate 200 may be substantially the same as or similar to the first heat dissipation substrate 100. Accordingly, same or similar reference numerals may be used to refer to the same or like elements and any further repetitive explanation concerning the above elements will be omitted.

In some implementations, a third heat dissipation member HS3 as a third heat spreader may be disposed on the second semiconductor device 40. The second semiconductor device 40 may have a third height that is smaller than the first height from the upper surface of the interposer 50. A height of the third heat dissipation member HS3 from the upper surface of the interposer 50 may be the same as the first height. The first heat dissipation member HS1 may be disposed on the second semiconductor device 40 and the second heat dissipation member HS2. The third heat dissipation member HS3 may be disposed on the second semiconductor device 40 to compensate for a height difference of the second semiconductor device 40 and may transfer heat from the second semiconductor device 40 to the first heat dissipation member HS1.

In some implementations, when the height of the second semiconductor device 40 is the same as the height of the first semiconductor device 30, the third heat dissipation member HS3 may be omitted.

The third heat dissipation member HS3 may include a third heat dissipation substrate 300 directly bonded to an upper surface of the second semiconductor device 40, a third micro channel 314 extending within the third heat dissipation substrate 300, and a third working fluid movably accommodated within the third micro channel 314.

The third heat dissipation substrate 300 may include a third lower substrate 310 and a third upper substrate 320. A lower surface of the third lower substrate 310 may be directly bonded to the upper surface of the second semiconductor device 40. A recess may be formed in an upper surface of the third lower substrate 310. The third upper substrate 320 may be directly bonded to the third lower substrate 310. The third upper substrate 320 may cover the recess of the third lower substrate 310 to define the third micro channel 314.

The third heat dissipation member HS3 may be thermally connected to the first heat dissipation member HS1 and may dissipate heat from the second semiconductor device 30 to the outside. The first heat dissipation member HS1 may be directly bonded to the third heat dissipation member HS2. The lower surface of the first lower substrate 110 may be directly bonded to an upper surface of the third upper substrate 320.

The third heat dissipation substrate 300 may be substantially the same as or similar to the first heat dissipation substrate 100. Accordingly, same or similar reference numerals may be used to refer to the same or like elements and any further repetitive explanation concerning the above elements will be omitted.

In some implementations, the interposer 50 may be disposed on the package substrate 20. The interposer 50 may be mounted on the package substrate 20 through solder bumps 58. A planar area of the interposer 50 may be smaller than a planar area of the package substrate 20. When viewed in plan view, the interposer 50 may be disposed within an area of the package substrate 20.

External connection pads may be formed on the lower surface of the package substrate 20, and the external connection members 28 for electrical connection with external devices may be disposed on the external connection pads. For example, the external connecting member 28 may include a solder ball. The semiconductor package 11 may be mounted on a module substrate using the solder balls to form a memory module.

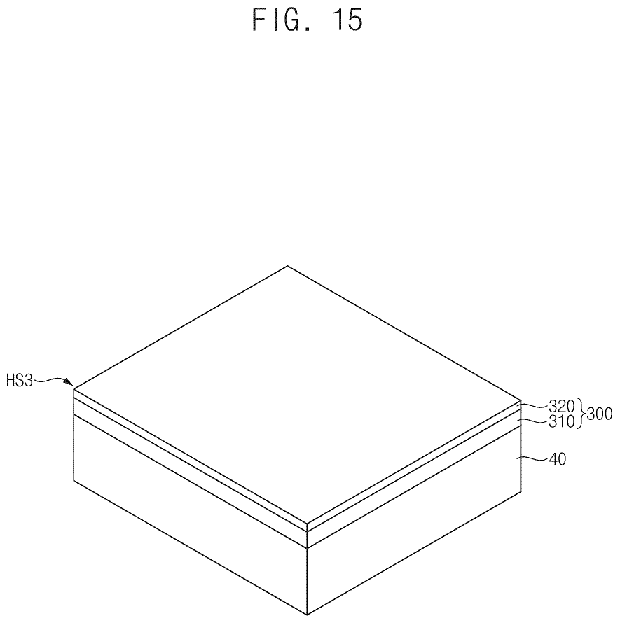

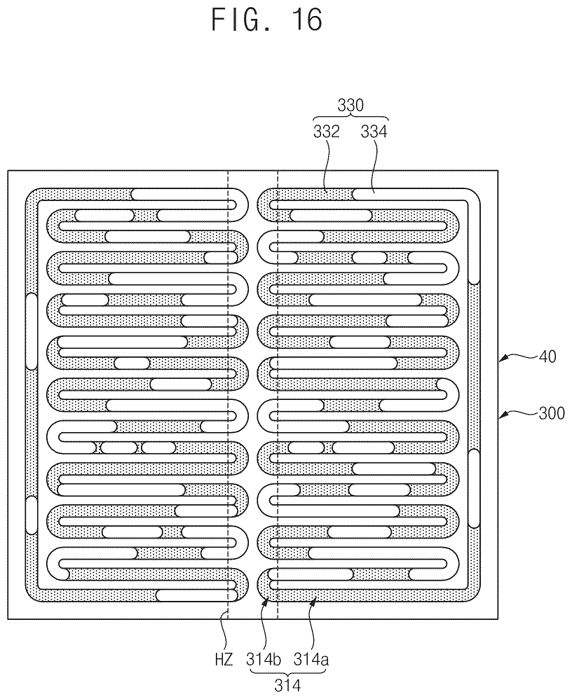

FIGS. 14 to 19 are views illustrating an example of a method of manufacturing a semiconductor package according to some implementations. FIG. 14 is an exploded perspective view illustrating an example of a process of bonding a third heat dissipation member on a second semiconductor device according to some implementations. FIG. 15 is a perspective view illustrating the third heat dissipation member bonded to the second semiconductor device of FIG. 14 according to some implementations. FIG. 16 is a plan view of FIG. 15 according to some implementations.

In FIGS. 14 to 16, a third heat dissipation member HS3 as a third heat spreader may be bonded to a second semiconductor device 40.

In some implementations, a third lower substrate 310 may be bonded to an upper surface of a second semiconductor device 40, and a third upper substrate 320 may be bonded to the third lower substrate 310 to form a third heat dissipation substrate 300 of the third heat dissipation member HS3. A planar area of the third heat dissipation member HS3 may be the same as a planar area of the second semiconductor device 40. In some implementations, after the third upper substrate 320 is bonded to the third lower substrate 310 to form the third heat dissipation member HS3, the third heat dissipation member HS3 may be bonded on the upper surface of the second semiconductor device 40.

For example, the third lower substrate 310 may be bonded to the upper surface of the second semiconductor device 40 by fusion bonding, anodic bonding, diffusion bonding, eutectic bonding, thermal compression bonding, etc. Similarly, the third upper substrate 320 is bonded to the third lower substrate 310 to form a third micro channel 314, and a working fluid may be injected into the third micro channel 314 to form the third heat dissipation member HS3.

In FIG. 16, the third micro channel 314 may have straight extension portions 314a extending in a straight line and curved extension portions 314b connecting the straight extension portions 314a. The curved extension portion 314b may be U-shaped. The second semiconductor device 40 may have a heat source region (HZ) as a hot spot where a relatively large amount of heat is emitted. The curved extension portions 314b of the third micro channel 314 may be arranged along the heat source region HZ of the second semiconductor device 40.

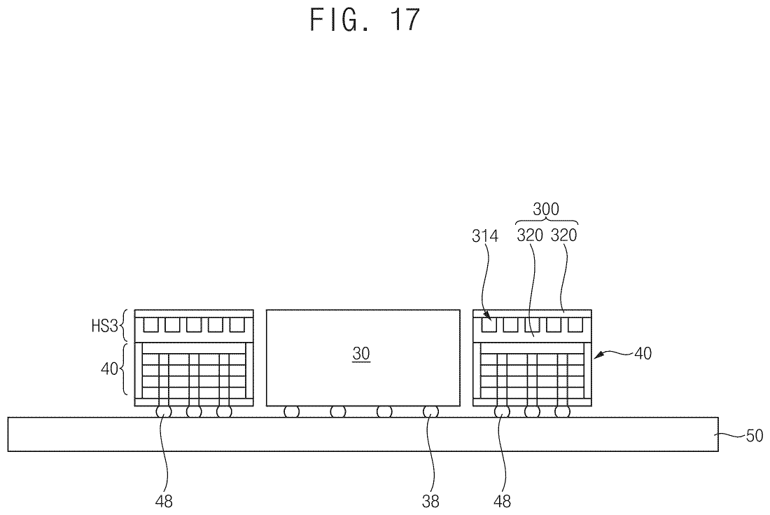

In FIG. 17, a first semiconductor device 30 and the second semiconductor device 40 may be mounted on an interposer 50. The first semiconductor device 30 and the second semiconductor device 40 may be arranged on the interposer 50 to be spaced apart from each other along a first direction. Two second semiconductor devices 40 may be disposed in both sides of the first semiconductor device 30. The first semiconductor device 30 may be mounted on the interposer 50 through solder bumps 38, and the second semiconductor device 40 may be mounted on the interposer 50 through solder bumps 48.

The second semiconductor device 40 may include a buffer die and a plurality of memory dies (chips) sequentially stacked on the buffer die. The buffer die and the memory die may be electrically connected to each other through through-silicon vias. The through-silicon vias may be electrically connected to each other by the solder bumps 38. The buffer die and the memory die may communicate data signals and control signals through the through-silicon vias.

The interposer 50 may be provided as a mounting substrate having connection wires therein. The interposer 50 may mount the first and second semiconductor devices 30 and 40 and electrically connect them to each other. The first and second semiconductor devices 30 and 40 may be connected to each other through the connection wires inside the interposer 50.

The first semiconductor device 30 may have a first height from an upper surface of the interposer 50, and the third heat dissipation member HS3 may have a fourth height from the upper surface of the interposer 50. For example, the first height may be substantially the same as the fourth height.

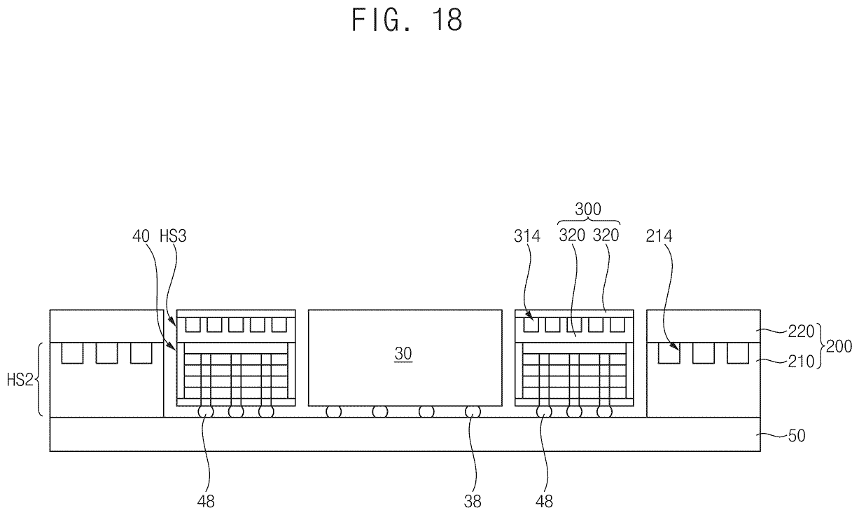

In FIG. 18, a second heat dissipation member HS2 as a second heat spreader may be disposed on the interposer 50.

In some implementations, a second lower substrate 210 may be bonded to the upper surface of the interposer 50, and a second upper substrate 220 may be bonded to the second lower substrate 210 to form a second heat dissipation substrate 200 of the second heat dissipation member HS2. In some implementations, after the second upper substrate 220 is bonded to the second lower substrate 210 to form the second heat dissipation member HS2, the second heat dissipation member HS2 may be bonded to the upper surface of the interposer 50.

For example, the second lower substrate 210 may be bonded to the upper surface of the interposer 50 by fusion bonding, anodic bonding, diffusion bonding, eutectic bonding, thermal compression bonding, etc. Similarly, the second upper substrate 220 may be bonded to the second lower substrate 210 to form a second micro channel 214, and a working fluid may be injected into the second micro channel 214 to form the second heat dissipation member HS2.

The second heat dissipation member HS2 may have a cavity in a middle region thereof to accommodate the first semiconductor device 30 and the second semiconductor devices 40. The first and second semiconductor devices 30 and 40 may be disposed within the cavity of the second heat dissipation member HS2. In some implementations, a plurality of the second heat dissipation members HS2 may be arranged to surround the first and second semiconductor devices 30 and 40.

The first semiconductor device 30 may have a first height from the an upper surface of the interposer 50, and the second heat dissipation member HS2 may have a second height from the upper surface of the interposer 50. For example, the first height may be substantially the same as the second height.

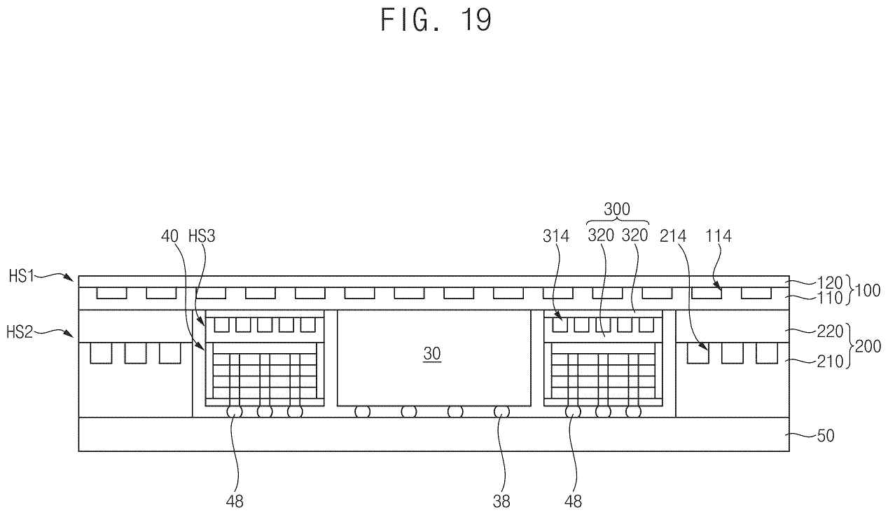

In FIG. 19, processed the same as or similar to the processes described with reference to FIG. 18 may be performed to dispose a first heat dissipation member HS1 as a first heat spreader on the first semiconductor device 30, the second heat dissipation member HS2, and the third heat dissipation member HS3.

The first heat dissipation member HS1 may be thermally connected to the second heat dissipation member HS2 and may dissipate heat from the first semiconductor device 30 to the outside. The first heat dissipation member HS1 may be directly bonded to the second heat dissipation member HS2. Heat from the first semiconductor device 30 may be dissipated to the outside through the first heat dissipation member HS1 or may be transferred to the second heat dissipation member HS2 and then be emitted to the outside. Additionally, heat from the first semiconductor device 30 may be directly transferred to the second heat dissipation member HS2 and then dissipated to the outside.

The first heat dissipation member HS1 may be thermally connected to the third heat dissipation member HS3 and may dissipate heat from the second semiconductor device 40 to the outside. The first heat dissipation member HS1 may be directly bonded to the third heat dissipation member HS3. Heat from the second semiconductor device 40 may be dissipated to the outside through the first heat dissipation member HS1 or may be transferred to the second heat dissipation member HS2 and then be emitted to the outside. Additionally, heat from the second semiconductor device 40 may be directly transferred to the second heat dissipation member HS2 and then dissipated to the outside.

Then, the interposer 50 on which the first and second semiconductor devices 30 and 40 are mounted may be disposed on the package substrate 20, and external connection members such as balls may be disposed on external connection pads on a lower surface of a package substrate 20 to complete a semiconductor package 11 of FIG. 13.

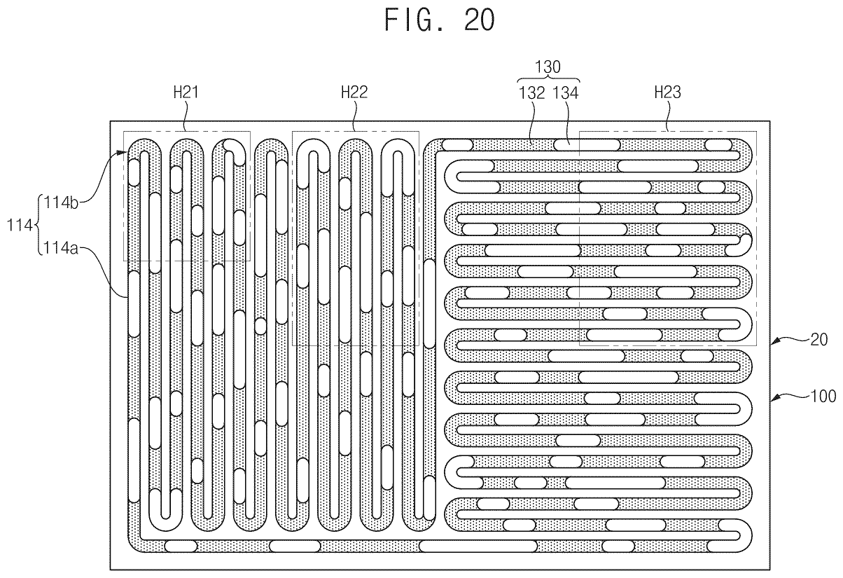

FIG. 20 is a plan view illustrating an example of a heat dissipation member bonded to a semiconductor device according to some implementations. In FIG. 20, a heat dissipation substrate 100 of a heat dissipation member may be directly bonded to one surface of a semiconductor device 30. The semiconductor device 30 may be a system on chip (SOC) that includes IP blocks such as CPU and GPU within one chip. The semiconductor device 30 may include a first heating region HZ1 that emits first heat, a second heating region HZ2 that emits second heat, and a third heating region HZ3 that emits third heat. The first to third heating regions HZ1, HZ2, and HZ3 may be respectively provided with the IP blocks and may be heat source regions of the semiconductor device 30 where a relatively large amount of heat is emitted.

In some implementations, the heat dissipation member may include a heat dissipation substrate 100 directly bonded to an inactive surface of the semiconductor device 30, a micro channel 114 extending within the heat dissipation substrate 100, and a working fluid 130 movably accommodated within the micro channel and including liquid slugs 132 and gaseous plugs 134 that are alternately disposed along an extending direction of the micro channel 114. The micro channel 114 may have straight extension portions 114a extending in a straight line and curved extension portions 114b connecting the straight extension portions 114a. The curved extension portion 114b may be U-shaped.

The curved extension portions 114b of the micro channel 114 may be arranged to overlap the first to third heat source regions HZ1, HZ2, and HZ3 of the semiconductor device 30. Since the curved extension portions 114b are arranged to overlap the first to third heat source regions HZ1, HZ2, and HZ3 that emit relatively high heat, the heat dissipation performance of the pulsating heat pipe may be further improved.

The semiconductor package may include semiconductor devices, such as logic devices or memory devices. For example, the semiconductor package may include logic devices, such as central processing units (CPUs), main processing units (MPUs), or application processors (APs), or the like, and volatile memory devices, such as DRAM devices, HBM devices, or non-volatile memory devices, such as flash memory devices, PRAM devices, MRAM devices, ReRAM devices, or the like. The electronic device may be embodied by a personal computer PC or a portable electronic device, such as a notebook, a cell phone, a personal digital assistant (PDA) and a camera.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package, comprising:
a mounting substrate;
a semiconductor device mounted on the mounting substrate; and
a first heat dissipation member disposed on the semiconductor device,
wherein the first heat dissipation member includes:
a first heat dissipation substrate bonded to an upper surface of the semiconductor device;
a first micro channel within the first heat dissipation substrate; and
a first working fluid accommodated in the first micro channel,
wherein the first working fluid includes liquid slugs and gaseous plugs that are alternately disposed along an extending direction of the first micro channel.

2. The semiconductor package of claim 1, wherein the first heat dissipation member includes a first heat dissipation portion overlapping the semiconductor device and a second heat dissipation portion extending horizontally from the first heat dissipation portion.

3. The semiconductor package of claim 1, wherein a width of the first micro channel is in a range of 100 μm to 1,000 μm, and a height of the first micro channel is in a range of 50 μm to 500 μm.

4. The semiconductor package of claim 1, wherein the first heat dissipation substrate includes:
a first lower substrate bonded to the upper surface of the semiconductor device and having a first recess formed in an upper surface of the first lower substrate; and
a first upper substrate bonded to the first lower substrate and covering the first recess to define the first micro channel.

5. The semiconductor package of claim 1, wherein the first heat dissipation member has a thickness in a range of 100 μm to 800 μm.

6. The semiconductor package of claim 1, wherein the first working fluid comprises a dielectric solution.

7. The semiconductor package of claim 1, wherein the first heat dissipation substrate comprises at least one of silicon (Si), silicon carbide (SiC), or aluminum nitride (AlN).

8. The semiconductor package of claim 1, further comprising:
a second heat dissipation member spaced apart from the semiconductor device on the mounting substrate,
wherein the first heat dissipation member is bonded to the second heat dissipation member.

9. The semiconductor package of claim 8, wherein the second heat dissipation member includes:
a second heat dissipation substrate bonded to the upper surface of the mounting substrate;
a second micro channel within the second heat dissipation substrate; and
a second working fluid accommodated in the second micro channel,
wherein the second working fluid includes liquid slugs and gaseous plugs that are alternately disposed along an extending direction of the second micro channel.

10. The semiconductor package of claim 1, further comprising:
a second semiconductor device spaced apart from the semiconductor device on the mounting substrate; and
a third heat dissipation member disposed on the second semiconductor device,
wherein the first heat dissipation member is bonded to the third heat dissipation member.

11. A semiconductor package, comprising:
a mounting substrate;
a first semiconductor device and a second semiconductor device mounted on the mounting substrate and spaced apart from each other; and
a first heat dissipation member disposed on the first semiconductor device and the second semiconductor device,
wherein the first heat dissipation member includes:
a first heat dissipation substrate bonded to an upper surface of the first semiconductor device;
a first micro channel within the first heat dissipation substrate; and
a first working fluid accommodated in the first micro channel,
wherein the first working fluid includes liquid slugs and gaseous plugs that are alternately disposed along an extending direction of the first micro channel.

12. The semiconductor package of claim 11, further comprising:
a second heat dissipation member spaced apart from the first semiconductor device and the second semiconductor device on the mounting substrate,
wherein the first heat dissipation member is disposed on the second heat dissipation member.

13. The semiconductor package of claim 12, wherein the second heat dissipation member includes:
a second heat dissipation substrate bonded to the upper surface of the mounting substrate;
a second micro channel within the second heat dissipation substrate; and
a second working fluid movably accommodated in the second micro channel,
wherein the second working fluid includes liquid slugs and gaseous plugs that are alternately disposed along an extending direction of the second micro channel.

14. The semiconductor package of claim 11, further comprising:
a third heat dissipation member disposed on the second semiconductor device,
wherein the first heat dissipation member is disposed on the third heat dissipation member.

15. The semiconductor package of claim 14, wherein the third heat dissipation member includes:
a third heat dissipation substrate bonded to the upper surface of the second semiconductor device;
a third micro channel within the third heat dissipation substrate; and
a second working fluid accommodated in the third micro channel,
wherein the second working fluid includes liquid slugs and gaseous plugs that are alternately disposed along an extending direction of the third micro channel.

16. The semiconductor package of claim 11, wherein the first heat dissipation substrate includes:
a first lower substrate bonded to the upper surface of the first semiconductor device, the first lower substrate having a first recess formed in an upper surface of the first lower substrate; and
a first upper substrate bonded to the first lower substrate and covering the first recess to define the first micro channel.

17. The semiconductor package of claim 11, wherein the first heat dissipation member has a thickness in a range of 100 μm to 800 μm.

18. The semiconductor package of claim 11, wherein the first working fluid comprises a dielectric solution.

19. The semiconductor package of claim 11, wherein the first heat dissipation substrate comprises at least one of silicon (Si), silicon carbide (SiC), or aluminum nitride (AlN).

20. A semiconductor package, comprising:
a mounting substrate;
a semiconductor device mounted on the mounting substrate;
a first heat dissipation member spaced apart from the semiconductor device on the mounting substrate; and
a second heat dissipation member disposed on the semiconductor device and the first heat dissipation member,
wherein the second heat dissipation member is bonded to the semiconductor device and the first heat dissipation member,
wherein the second heat dissipation member includes:
a second heat dissipation substrate bonded to an upper surface of the semiconductor device; and
a pulsating heat pipe within the second heat dissipation substrate.
